(19) United States
(12) Patent Application Publication
(10) Pub. No.: US 2014/0242407 A1
(43) Pub. Date: Aug. 28, 2014

(54) In-situ Compressed Specimen for Evaluating Mechanical Property of Copper Interconnection Micro Column and Preparation Method thereof

(71) Applicants: Hong Wang, Shanghai (CN); Zhaoyu Wang, Shanghai (CN); Ping Cheng, Shanghai (CN); Guifu Ding, Shanghai (CN); Ting Gu, Shanghai (CN); Huiying Wang, Shanghai (CN); Congchun Zhang, Shanghai (CN)

(72) Inventors: Hong Wang, Shanghai (CN); Zhaoyu Wang, Shanghai (CN); Ping Cheng, Shanghai (CN); Guifu Ding, Shanghai (CN); Ting Gu, Shanghai (CN); Huiying Wang, Shanghai (CN); Congchun Zhang, Shanghai (CN)

(73) Assignee: Shanghai Jiao Tong University, Shanghai (CN)

(21) Appl. No.: 14/345,392

(22) PCT Filed: Mar. 25, 2013
(86) PCT No.: PCT/CN2013/073133

§ 371 Date: Mar. 17, 2014

(30) Foreign Application Priority Data
Jul. 17, 2012 (CN) 20120247658.3
Feb. 1, 2013 (CN) 201310039874.3

(51) Int. Cl. B81C 1/00

(52) U.S. Cl. CPC B81C 1/00015
USPC 428/600; 205/122

(57) ABSTRACT

An in-situ compressed specimen of copper interconnection micro column, which is a circular metal column formed in a PDMS hole, includes: a specimen part and a fixed end part for fixing the specimen; wherein the fixed end part is a circular or square plate structure, the specimen part is an upper part of the fixed end part; a main body of the present invention is of micron order, a forced direction of the specimen is consistent with a growth direction of the metal column. A method of electroplating copper column by adopting PDMS as template substrate is applied to overcome a problem that TSV is corrosive to the copper column during a silicon etching process so as to affect a mechanical property accuracy test, the method is advanced in shortening test process period, achieving good reproducibility and high yield.

### CROSS REFERENCE OF RELATED APPLICATION

This is a U.S. National Stage under 35 U.S.C 371 of the International Application PCT/CN2013/073133, filed Mar. 25, 2013, which claims priority under 35 U.S.C. 119(a-d) to CN 201310039874.3, filed Feb. 1, 2013.

### BACKGROUND OF THE PRESENT INVENTION

1. Field of Invention

The invention relates to a compressed specimen for testing mechanical property of copper interconnection micro column and a preparation method thereof, specifically to an in-situ compressed specimen for simulating TSV copper interconnection material mechanical property test and a preparation method thereof.

2. Description of Related Arts

TSV (Through Silicon Vias) lamination interconnection technique can improve three-dimensional integration level and reduce interconnection delay with advantage of shortening the distance, it is an important direction for microelectronic technology development. As the preparation technology and structure size of copper interconnection material in TSV are different from those of macro block copper material, the basic characteristics of material yield strength, breaking strength and Young modulus are obviously different from those of macro material.

PDMS is a common thermoplastic elastomer with excellent graphic reproducibility. It is a soft material with low Young modulus and easy to be compressed and deformed. PDMS is advanced in excellent membrane elasticity, high strength, easy forming and low surface energy, therefore it is easy to take the membrane off from the mould without damage to the module when membrane is formed. Therefore PDMS has been widely applied in the field of MEMS, for example, a PDMS membrane structure based MEMS broadband piezoelectric energy harvester claimed in Chinese patent CN201010263850.2, PDMS is used as structure membrane to sense external vibration so as to generate excitation output voltage. The present invention adopts PDMS as the module for preparing metal column by utilizing high strength and excellent elasticity of PDMS membrane.

The existing membrane mechanical property test is mostly based on nano-indentation method and membrane uniaxial tension method, micro-compression method is not adopted to test mechanical property of material. Nano-indentation is a method of obtaining mechanical parameter of specimen through loading-unloading curve during nano-indentation hardness test, it is a public method which cannot obtain breaking strength and other parameters of the material.

The technology of preparing specimen by adopting membrane uniaxial tension method is relatively simple and easy to obtain test data, for example, a uniaxial tensile specimen (publication number is 101149317A) proposed in Chinese patent ZL2007 1 0047682.1, the present invention introduces a uniaxial tensile specimen of mechanical property test technique for membrane mechanical property test, however the tensile direction in the membrane uniaxial tension method is vertical to the growth direction of electroplated layer, which cannot obtain in-situ mechanical characteristic parameters of TSV copper material. In the case of no detailed microscale and mechanical characteristic parameters of in-situ copper material, copper TSV structure design and analogue simulation will reference mechanical parameters of macro block copper material so as to cause certain problem about reliability in TSV copper interconnection structure design and impede process of industrialization.

In-situ tensile specimen preparing technology and test method are relatively difficult, for example, the patent for invention with application number of 201210050952.5, the patent application claims an in-situ tensile specimen for TSV copper interconnection material mechanical property test, however the in-situ tensile specimen needs an upper fixed end part and a lower fixed end part, and they are partly in vertical direction with the in-situ tensile specimen, therefore they are hard to be copied. And the sample part has small size, the two fixed ends are hard to be clamped during test so as to make the test harder.

The Chinese patent application with publication number of 102768148A, the patent claims an in-situ compressed specimen for TSV copper interconnection material mechanical property test, the specimen includes a specimen part and fixed ends for fixing specimen, the specimen part is circular metal column formed in through silicon vias; the specimen part is on the upper end part of the fixed end. However, the patent specimen is prepared by adopting common technique, it is not easy to form the circular metal column in the through silicon vias, the process of etching silicon may cause damage to micro column so as to cause accuracy problem of mechanical property test.

### SUMMARY OF THE PRESENT INVENTION

For shortcomings of the above conventional technique, a purpose of the invention is to provide a copper interconnection micro column mechanical property in-situ compressed specimen and a preparation method thereof, the specimen which only needs a fixed end is easy to achieve the technology, and only one end is fixed in a test, therefore it is easier to accurately test mechanical property of the specimen.

In an aspect of the invention, a preparation method of copper interconnection micro column mechanical property in-situ compressed specimen is provided, wherein PDMS is used as a template substrate of a electroplated column to completely extract a metal column in the interconnected hole as the specimen part, that is to electroplate metal in a PDMS hole after the PDMS is graphical, then the PDMS is directly stripped off to expose the metal column after a curing treatment. Specifically, the preparation method comprises steps of:
(a) Sputtering a titanium seed layer with thickness of 0.2-0.5 μm on a glass sheet.
(b) Electroplating a metal layer with total thickness of 200-300 μm on the seed layer (nickel or copper or nickel and copper alternative);
(c) Spin coating a negative gum layer with thickness of 50-200 μm;
(d) After etching the negative gum with RIE, electroplating nickel in an etched hole with a diameter of 5-50 μm and depth of 50-200 μm;
(e) Removing photo-resist and the seed layer to expose a metal column which adopts the metal layer obtained in the step (b) as substrate, and the metal column is the nickel column obtained by electroplating process in the step (d);
(f) Spin coating a PDMS layer on the metal column obtained in the step (e) and the substrate of the metal layer for a curing treatment;
(g) Directly stripping PDMS from the nickel column;
(h) Sputtering a titanium seed layer with thickness of 0.15-0.25 μm on the PDMS at first, then sputtering a copper seed layer with thickness of 0.5-0.8 μm;
(i) Electroplating copper on the copper seed layer in the step (h) to form a copper interconnection micro column structure with a high aspect ratio;
(j) Stripping the PDMS from the copper column to expose the copper column.

Preferably, in the step (b), the metal layer is a structure formed by alternatively electroplating copper and nickel and guaranteeing the last layer to be nickel layer, or formed by electroplating nickel entirely.

In the other aspect of the invention, a copper interconnection micro column mechanical property in-situ compressed specimen prepared by the above method is provided, wherein the in-situ compressed specimen comprises a specimen part and a fixed end part for fixing the specimen, the specimen part is circular metal column formed in PDMS; an end of the specimen part is fixed above the fixed end part, a clamp is used to fix the fixed end part, and the other end of the specimen part is applied pressure, a forced direction of the specimen part is consistent with a growth direction of the circular metal column to achieve a specimen compression test.

Preferably, the specimen part is of micron order, thickness of the fixed end part is from micron order to millimeter order.

Preferably, the specimen part is a circular metal column formed in a PDMS hole and made of electrodeposited copper, rather than a copper micro column simulating a TSV structure prepared in through silicon vias.

Preferably, the fixed end part is a circular or square plate structure made of copper or nickel.

Preferably, the fixed end part is 500-5000 μm long and 300-600 μm thick.

The in-situ compressed specimen of the invention is a metal micro column structure which is prepared by adopting the PDMS as a module and has the high aspect ratio. An exposed metal micro column array is separated into single copper columns, that is to obtain above the in-situ compressed specimen. An end of the specimen part is fixed on the fixed end part, a clamp is used to fix the fixed end part, and the other end of the specimen part is applied pressure, the forced direction of the specimen is consistent with the growth direction of the circular metal column to achieve the specimen compression test. A specimen stress-strain curve can be obtained through a record of load and displacement changes during the test so as to obtain basic mechanical parameters, comprising yield strength, breaking strength, Young modulus and so on.

The above method of the present invention is to obtain the copper interconnection micro column structure which is prepared by adopting the PDMS as the module and has the high aspect ratio, rather than to prepare the micro column in the through silicon vias, so as to avoid damage of etching silicon to the micro column; the in-situ compressed specimen for simulating the TSV copper interconnection material mechanical property test is provided such that the obtained mechanical parameters are more available to practical application and an existing problem of imperfect characterization of TSV copper interconnection material mechanical property.

Compared with the conventional technique, the present invention has advantages as follows:

Compared with the conventional domestic micro tensile specimen, firstly, the copper interconnection micro column in-situ compressed specimen structure designed by the present invention for simulating the TSV has a main body size of micron order, which is approximately same as a TSV copper interconnection main body size in actual production, the forced direction of the specimen is consistent with the growth direction of the copper column, which is more similar to a forming process and a structure of TSV copper interconnection in practical application. Secondly, a preparing process thereof is practical, compared with the process of an electroplating copper column by adopting silicon as substrate, the technology of the electroplating copper column by adopting the PDMS as the template substrate overcomes a problem that the copper column is corroded during a TSV etching silicon process so as to affect accurate test of the mechanical property, the technology is advanced in shortening process period, excellent reproducibility and high yield; finally, the present invention adopts a frameless structure and uniaxial compression, and only one fixed end is needed, therefore the technology is more simple, and the obtained copper micro column structure is more complete and easier to test, and the mechanical property of TSV copper interconnection material can be tested more directly.

### BRIEF DESCRIPTION OF THE DRAWINGS

Characteristics, purpose and advantages of the invention will be further illustrated through reading and reference of detailed description of unrestricted embodiment in the following figures

FIG. 1 is a flow chart of a copper interconnection micro column in-situ compressed specimen structure according to the present invention;

FIG. 2 is a diagram of the copper interconnection micro column in-situ compressed specimen structure according to the present invention embodiment for simulating TSV;

In the FIG. 2: 1 indicates the metal column, and 2 indicates the fixed end part;

FIG. 3 is a compression and fixing diagram of the copper interconnection micro column in-situ compressed specimen structure according to the present invention embodiment for simulating TSV;

In the FIG. 3: 3 indicates the fixed end clamp, and 4 indicates the forced end.

### DETAILED DESCRIPTION OF THE PREFERRED EMBODIMENT

Preferred embodiments will be combined to provide detailed description for the present invention. The following embodiment will help the technician in the field further understanding the present invention, but not limiting the present invention in any form. It should be noted that several deformations and improvements can be made by common technician in the field in the premise of not out of the present invention concept. These belong to protective scope of the present invention.

### Preferred Embodiment 1

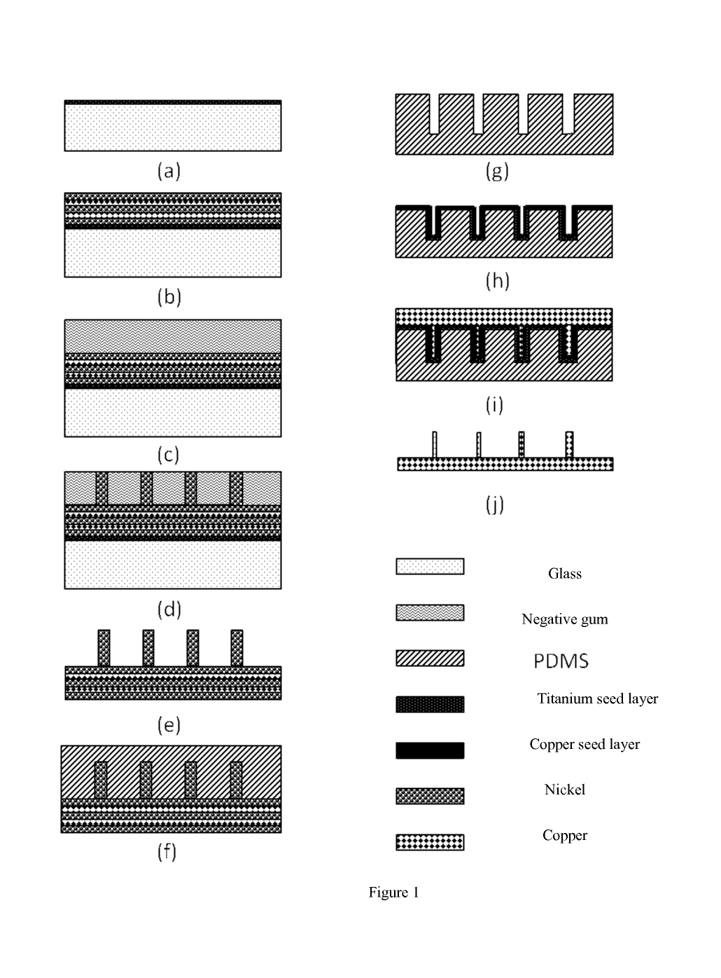

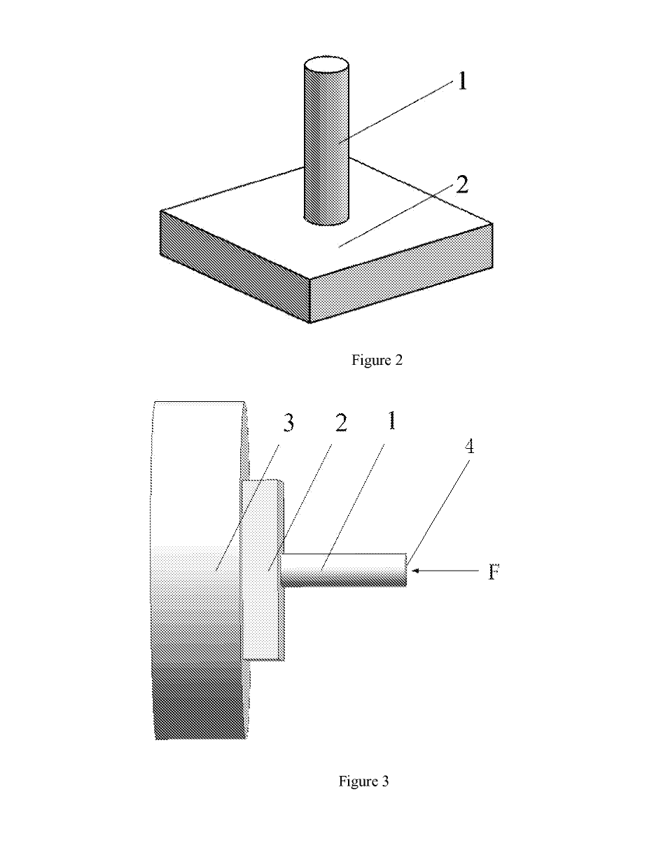

FIG. 1 shows a specific preparation method. The preparation method comprises steps of: sputtering a titanium seed layer with thickness of about 0.2 μm on a glass sheet; electroplating a copper-nickel layer with total thickness of about 200 μm on the seed layer, wherein the copper-nickel layer is formed by electroplating copper and nickel alternatively and guaranteeing the last layer is nickel layer; spin coating a negative gum layer with thickness of 50 μm on the nickel layer; graphing the negative gum by adopting RIE etching method to form a hole with a diameter of 5 μm and depth of 50 μm; electroplating nickel in the etched hole; removing photo-resist and the seed layer to expose a nickel column adopting copper and nickel as substrate; spin coating a PDMS layer on the nickel column; directly stripping off PDMS from the nickel column after a curing treatment; sputtering a titanium seed layer with thickness of 0.2 μm and a copper seed layer with thickness of 0.5 μm on the stripped PDMS; electroplating copper to form a copper interconnection micro column structure with high aspect ratio; finally stripping off PDMS from the copper column to expose the copper column; and obtaining the specimen as shown in the FIG. 2. That is to provide the copper interconnection micro column in-situ compressed specimen structure, comprising a specimen part and a fixed end part for fixing the specimen.

The specimen part according to the preferred embodiment is the metal column formed in a PDMS hole, that is the specimen part made of electrodeposited copper. The copper interconnection micro column structure which is prepared by adopting the PDMS as a module and has a high aspect ratio is not prepared in through silicon vias so as to avoid damage of etching silicon to the micro column.

Thickness and size of the specimen part 1 and the fixed end part 2 are of micron order.

Specifically, in the preferred embodiment, the specimen part 1 is in a shape of a circular metal column with a diameter of 5 μm and height of 50 μm.

In the preferred embodiment, the specimen part 1 is made of copper.

In the preferred embodiment, the fixed end part 2 is of a square plate structure with side length of 500 μm and thickness of 500 μm.

In the preferred embodiment, the fixed end part 2 is made of copper.

As shown in FIG. 3, when the preferred embodiment is used for measurement, an end of the specimen part is fixed by the fixed end part 2, the other end of the specimen part is applied pressure in a horizontal direction to achieve a specimen compression test. A specimen stress-strain curve can be obtained through a record of load and displacement changes during the test so as to obtain basic mechanical parameters, comprising yield strength, Young modulus and so on.

### Preferred Embodiment 2

FIG. 1 is a detailed preparing method. The method comprises steps of: sputtering a titanium seed layer with thickness of about 0.4 μm on a glass sheet; electroplating a nickel layer with total thickness of 250 μm on the seed layer; spin coating negative gum with thickness of 150 μm on the nickel layer; graphing the negative gum by using an RIE etching method to form a hole with a diameter of 25 μm and depth of 150 μm; electroplating nickel in the etched hole; removing photo-resist and the seed layer to expose a nickel column which adopts nickel as substrate; spin coating a PDMS layer on the nickel column; directly stripping off PDMS from the nickel column after a curing treatment; sputtering a titanium seed layer with thickness of 0.15 μm and a copper seed layer with thickness of 0.6 μm on the PDMS which has been stripped off; electroplating copper to form a copper interconnection micro-column structure with a high aspect ratio; finally stripping off the PDMS from the copper column to expose the copper column; obtaining the specimen as shown in FIG. 2. That is to provide the copper interconnection micro column in-situ compressed specimen structure for simulating the TSV, comprising a specimen part and a fixed end part for fixing the specimen.

The specimen part according to the preferred embodiment is metal column formed in a PDMS hole, which is the specimen part 1, and is made of the electrodeposited copper. The copper interconnection micro column structure with the high aspect ratio is prepared by adopting the PDMS as a module and not prepared in through silicon vias so as to avoid damage of etching silicon to the micro column.

Thickness and size of the specimen part 1 and fixed end part 2 are of micron order.

Specifically, in the preferred embodiment, the specimen part 1 is in a shape of a circular metal column with a diameter of 25 μm and height of 150 μm.

In the preferred embodiment, the specimen part 1 is made of copper.

In the preferred embodiment, the fixed end part 2 is in a shape of a square plate structure with side length of 3000 μm and thickness of 450 μm.

In the preferred embodiment, the specimen fixed end part 2 is made of copper.

As shown in FIG. 3, when the preferred embodiment is used for measurement, an end of the specimen part is fixed by the fixed end part 2, and an end of the specimen can be applied pressure in a horizontal direction to achieve a specimen compression test. A specimen stress-strain curve can be obtained through a record of load and displacement changes during the test so as to obtain basic mechanical parameters, comprising yield strength, breaking strength, Young modulus and so on.

### Preferred Embodiment 3

FIG. 1 shows a detailed preparing method. The method comprises steps of: sputtering a titanium seed layer with thickness of about 0.5 μm on a glass sheet; electroplating a copper-nickel layer with total thickness of 250 μm on the seed layer, wherein the copper-nickel layer is formed by electroplating copper and nickel alternatively and guaranteeing the last layer is nickel layer; spin coating a negative gum layer with thickness of 200 μm on the nickel layer; graphing negative gun by adopting RIE etching method to form a hole with a diameter of 5 μm and depth of 50 μm; electroplating nickel in the etched hole; removing photo-resist and the seed layer to expose the nickel column adopting copper and nickel as substrate; spin coating a PDMS layer on the nickel column; directly stripping off PDMS from the nickel column after a curing treatment; sputtering a titanium seed layer with thickness of 0.25 μm and a copper seed layer with thickness of 0.8 μm on the stripped PDMS; electroplating copper to form a copper interconnection micro column structure with high aspect ratio; finally stripping off PDMS from the copper column to expose the copper column; and obtaining the specimen as shown in the FIG. 2. That is to provide the copper interconnection micro column in-situ compressed specimen structure, comprising a specimen part and a fixed end part for fixing the specimen.

The specimen part according to the preferred embodiment is the metal column formed in a PDMS hole, that is the specimen part 1 made of electrodeposited copper. The copper interconnection micro column structure which is prepared by adopting the PDMS as a module and has a high aspect ratio is not prepared in through silicon vias so as to avoid damage of etching silicon to the micro column

Thickness and size of the specimen part 1 and the fixed end part 2 are of micron order.

Specifically, in the preferred embodiment, the specimen part 1 is in a shape of a circular metal column with a diameter of 50 μm and height of 200 μm.

In the preferred embodiment, the specimen part 1 is made of copper.

In the preferred embodiment, the fixed end part 2 is in a shape of a square plate structure with side length of 5000 μm and thickness of 600 μm.

In the preferred embodiment, the specimen fixed end part 2 is made of copper.

As shown in FIG. 3, when the preferred embodiment is used for measurement, an end of the specimen part is fixed by the fixed end part 2, and an end of the specimen can be applied pressure in a horizontal direction to achieve a specimen compression test. A specimen stress-strain curve can be obtained through a record of load and displacement changes during the test so as to obtain basic mechanical parameters, comprising yield strength, breaking strength, Young modulus and so on.

In the above preferred embodiments, compared with the conventional membrane specimen, a main body size of the specimen is of micron order, which is approximately same as a TSV copper interconnection main body size in actual production, and the forced direction of the specimen is consistent with the growth direction of the copper column, the mechanical parameters obtained through compression test can truly reflect mechanical characteristics of the TSV copper interconnection material, which will effectively improve truth of TSV copper interconnection material mechanical characteristic parameters in 3D package design and analogue simulation and play an important role in product development, application and service life predication and improvement of reliability. The copper interconnection micro column compressed specimen according to the present invention has the copper interconnection micro column structure which is prepared by adopting the PDMS as the module and has the high aspect ratio, rather than prepares micro column in the through silicon vias, so as to avoid damage of etching silicon to the micro column.

The purpose, technical proposal and beneficial effect of the present invention are further stated through detailed description of embodiments. The present invention is applicable to simulate mechanical property test characterization of copper interconnection material in TSV, and meanwhile it has corresponding effect on other micro metal material test.

Above is description of embodiment of the present invention. It should be understood that the present invention is not limited to above special implementation mode, the technician in the field can make various deformations or amendment in the scope of claims, this will not affect actual contents of the invention.

1-9. (canceled)

10. A preparation method of in-situ compressed specimen for evaluating mechanical property of copper interconnection micro column, wherein the preparation method comprises steps of:
(a) Sputtering a titanium seed layer with thickness of 0.2-0.5 μm on a glass sheet;
(b) Electroplating a metal layer with total thickness of 200-300 μm on the seed layer;
(c) Spin coating a negative gum layer with thickness of 50-200 μm;
(d) After etching the negative gum with RIE, electroplating nickel in an etched hole with a diameter of 5-50 μm and depth of 50-200 μm;
(e) Removing photo-resist and the seed layer to expose a metal column with the metal layer prepared in the step (b) as substrate, the metal column is the nickel column obtained by electroplating in the step (d);
(f) Spin coating a PDMS layer on the metal column obtained in the step (e) and the metal layer substrate thereof for a solidifying treatment;
(g) Directly stripping PDMS from the nickel column;
(h) Sputtering a titanium seed layer with thickness of 0.15-0.25 μm on the PDMS at first, and then sputtering a copper seed layer with thickness of 0.5-0.8 μm;
(i) Electroplating copper on the copper seed layer in the step (h) to form a copper interconnection micro column structure with a high aspect ratio;
(j) Stripping the PDMS from the copper column to expose the copper column.

11. The preparation method, as recited in claim 10, wherein in the step (b) the metal layer is a structure formed by alternatively electroplating copper and nickel and guaranteeing the last layer to be nickel layer, or formed by electroplating nickel entirely.

12. An in-situ compressed specimen prepared by the preparation as recited in claim 10, comprising: a specimen part and a fixed end part for fixing said specimen, said specimen part is a circular metal column formed in a PDMS hole; an end of said specimen part is fixed on said fixed end part, a clamp is used to fix said fixed end part and the other end of said specimen part is applied pressure, a forced direction of the specimen part is consistent with a growth direction of said circular metal column to realize a specimen compression test.

13. An in-situ compressed specimen prepared by the preparation as recited in claim 11, comprising: a specimen part and a fixed end part for fixing said specimen, said specimen part is a circular metal column formed in a PDMS hole; an end of said specimen part is fixed on said fixed end part, a clamp is used to fix said fixed end part and the other end of said specimen part is applied pressure, a forced direction of the specimen part is consistent with a growth direction of said circular metal column to realize a specimen compression test.

14. The in-situ compressed specimen, as recited in claim 12, wherein said specimen part is of micron order, thickness of said fixed end part is from micron order to millimeter order.

15. The in-situ compressed specimen, as recited in claim 13, wherein said specimen part is of micron order, thickness of said fixed end part is from micron order to millimeter order.

16. The in-situ compressed specimen, as recited in claim 14, wherein said specimen part is a circular metal column with a diameter of 5-50 μm and height of 50-200 μm.

17. The in-situ compressed specimen, as recited in claim 15, wherein said specimen part is a circular metal column with a diameter of 5-50 μm and height of 50-200 μm.

18. The in-situ compressed specimen, as recited in claim 12, wherein said specimen part is made of electrodeposited copper.

19. The in-situ compressed specimen, as recited in claim 14, wherein said specimen part is made of electrodeposited copper.

20. The in-situ compressed specimen, as recited in claim 16, wherein said specimen part is made of electrodeposited copper.

21. The in-situ compressed specimen, as recited in claim 12, wherein said fixed end part is of a circular or square plate structure.

22. The in-situ compressed specimen, as recited in claim 14, wherein said fixed end part is of a circular or square plate structure.

23. The in-situ compressed specimen, as recited in claim 16, wherein said fixed end part is of a circular or square plate structure.

24. The in-situ compressed specimen, as recited in claim 21, wherein said fixed end part is made of copper or nickel.

25. The in-situ compressed specimen, as recited in claim 22, wherein said fixed end part is made of copper or nickel.

26. The in-situ compressed specimen, as recited in claim 23, wherein said fixed end part is made of copper or nickel.

27. The in-situ compressed specimen, as recited in claim 21, wherein said fixed end part is 500-5000 μm long and 300-600 μm thick.

28. The in-situ compressed specimen, as recited in claim 22, wherein said fixed end part is 500-5000 μm long and 300-600 μm thick.

29. The in-situ compressed specimen, as recited in claim 23, wherein said fixed end part is 500-5000 μm long and 300-600 μm thick.
